(19) United States
(12) Patent Application Publication
(10) Pub. No.: US 2026/0213438 A1
(43) Pub. Date: Jul. 23, 2026

(54) CONNECTION STRUCTURE OF WIRE AND CIRCUIT BOARD AND TEMPERATURE MEASUREMENT UNIT

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventor: Nobuyuki MATSUMURA, Osaka (JP)

(21) Appl. No.: 19/142,960

(22) PCT Filed: Dec. 7, 2023
(86) PCT No.: PCT/JP2023/043804

§ 371 Date: Jun. 25, 2025

(30) Foreign Application Priority Data
Dec. 26, 2022 (JP) 2022-208253

(51) Int. Cl. H01R 12/53; G01K 7/22; H05K 1/181

(52) U.S. Cl. CPC H01R 12/53; G01K 7/22; H05K 1/181; H05K 2201/10151; H05K 2201/10356

(57) ABSTRACT

A connection structure 1 of a wire 20 and a circuit board 10 includes the wire 20 including a core wire 21 and an insulation coating 22 covering an outer periphery of the core wire 21, the circuit board 10 including a wire land to be connected to the core wire 21 by soldering, and a rigid board 30 to be disposed to overlap the circuit board 10 in a thickness direction of the circuit board 10. The rigid board 30 includes an accommodating portion 33 penetrating in the thickness direction and open in a direction orthogonal to the thickness direction. The accommodating portion 33 includes a core wire accommodating portion 35 for accommodating the core wire 21 and is disposed to overlap the wire land in the thickness direction.

### TECHNICAL FIELD

The present disclosure relates to a connection structure of a wire and a circuit board and a temperature measurement unit.

### BACKGROUND

Conventionally, a temperature sensor described in Japanese Patent Laid-Open Publication No. 2012-037384 (Patent Document 1) is known. This temperature sensor is provided with a thermistor for measuring a temperature and a molded resin portion for integrating the thermistor and a bracket. The bracket is provided with a thermistor temporary holding portion for temporarily holding the thermistor and a wire temporary holding portion for temporarily holding a wire drawn out to the outside of the molded resin portion.

### PRIOR ART DOCUMENT

### Patent Document

Patent Document 1: JP 2012-037384 A

### SUMMARY OF THE INVENTION

### Problems to be Solved

In the above configuration, since the molded resin portion is formed to cover the thermistor, a connected part of the thermistor and the wire and the bracket for temporarily holding the thermistor and the wire, the molded resin portion tends to be enlarged. Thus, if a routing space for the temperature sensor is narrow and the temperature sensor needs to be reduced in height, it may be difficult to adopt the above configuration.

Differently from the above configuration, it is thought to configure a temperature sensor by electrically connecting a wire to a circuit board mounted with a thermistor. It is an important issue not only for the temperature sensor, but also for configurations of various applications to enable a height reduction of such a connection structure of the wire and the circuit board.

### Means to Solve the Problem

The present disclosure is directed to a connection structure of a wire and a circuit board, the connection structure being provided with a wire including a core wire and an insulation coating covering an outer periphery of the core wire, a circuit board including a wire land to be connected to the core wire by soldering, and a rigid board to be disposed to overlap the circuit board in a thickness direction of the circuit board, the rigid board including an accommodating portion penetrating in the thickness direction and open in a direction orthogonal to the thickness direction, and the accommodating portion including a core wire accommodating portion for accommodating the core wire, the accommodating portion being disposed to overlap the wire land in the thickness direction.

### Effect of the Invention

According to the present disclosure, it is possible to provide a connection structure of a wire and a circuit board, which can be reduced in height.

### BRIEF DESCRIPTION OF THE DRAWINGS

FIG. 1 is a perspective view of a temperature measurement unit according to a first embodiment.

FIG. 2 is an exploded perspective view of the temperature measurement unit.

FIG. 3 is a plan view of the temperature measurement unit with one wire omitted.

FIG. 4 is a section along A-A of FIG. 3.

FIG. 5 is a perspective view of the temperature measurement unit provided with heat shrinkable tubes and a protecting member.

FIG. 6 is a perspective view of a battery module.

FIG. 7 is a plan view of the battery module.

FIG. 8 is a section along B-B of FIG. 7.

FIG. 9 is an enlarged perspective view of a bracket.

FIG. 10 is a perspective view showing a fuse unit according to a second embodiment.

### DETAILED DESCRIPTION TO EXECUTE THE INVENTION

### Description of Embodiments of Present Disclosure

First, embodiments of the present disclosure are listed and described.

(1) The connection structure of the wire and the circuit board of the present disclosure is provided with a wire including a core wire and an insulation coating covering an outer periphery of the core wire, a circuit board including a wire land to be connected to the core wire by soldering, and a rigid board to be disposed to overlap the circuit board in a thickness direction of the circuit board, the rigid board including an accommodating portion penetrating in the thickness direction and open in a direction orthogonal to the thickness direction, and the accommodating portion including a core wire accommodating portion for accommodating the core wire, the accommodating portion being disposed to overlap the wire land in the thickness direction.

According to this configuration, the shape and dimension in the thickness direction of solder are easily controlled by filling the solder for connecting the wire and the circuit board into the accommodating portion. Therefore, the connection structure of the wire and the circuit board can be reduced in height.

(2) Preferably, in the connection structure of the wire and the circuit board of (1), the accommodating portion includes a plated portion formed on at least a part of an inner wall of the accommodating portion.

According to this configuration, the solder is more easily filled into the accommodating portion. Further, the connection strength of the solder can be enhanced by connecting the solder and plated portion.

(3) Preferably, in the connection structure of the wire and the circuit board of (2), a dimension in the thickness direction of the plated portion has a minus tolerance with respect to a dimension in the thickness direction of the rigid board.

According to this configuration, it can be suppressed that the plated portion is formed outside the accommodating portion. Therefore, the leakage of the solder to the outside of the accommodating portion can be suppressed.

(4) Preferably, in the connection structure of the wire and the circuit board of any one of (1) to (3), the accommodating portion includes an opening end open in a direction orthogonal to the thickness direction and an insulation coating accommodating portion disposed continuously with the core wire accommodating portion on the opening end side for accommodating the insulation coating.

According to this configuration, the insulation coating can be accommodated into the accommodating portion. Thus, a part of the wire accommodated in the insulation coating accommodating portion can be restricted from moving with respect to the rigid board. Therefore, it can be suppressed that a stress is generated in a connected part of the core wire and the wire land due to a stress or vibration applied to the wire. Further, it can be suppressed that the core wire is damaged in a part not covered by the solder due to the concentration of the vibration or stress applied to the wire on the core wire.

(5) Preferably, in the connection structure of the wire and the circuit board of (4), the insulation coating accommodating portion includes a rounded round portion in an end region including the opening end and is formed to be wider toward the opening end.

According to this configuration, it can be suppressed that the insulation coating is damaged by contacting an end part of the accommodating portion on the opening end side.

(6) Preferably, in the connection structure of the wire and the circuit board of any one of (1) to (5), the rigid board includes a resist on a surface to be disposed on a side opposite to the circuit board in the thickness direction.

According to this configuration, the adhesion of the solder to the surface of the rigid board can be suppressed.

(7) A temperature measurement unit of the present disclosure is provided with the connection structure of the wire and the circuit board of any one of (1) to (6), and a thermistor to be mounted on the circuit board.

According to this configuration, the temperature measurement unit can be reduced in height.

### Details of Embodiments of Present Disclosure

Hereinafter, an embodiment of the present disclosure is described. The present disclosure is not limited to these illustrations, but is represented by claims and intended to include all changes in the scope of claims and in the meaning and scope of equivalents.

### First Embodiment

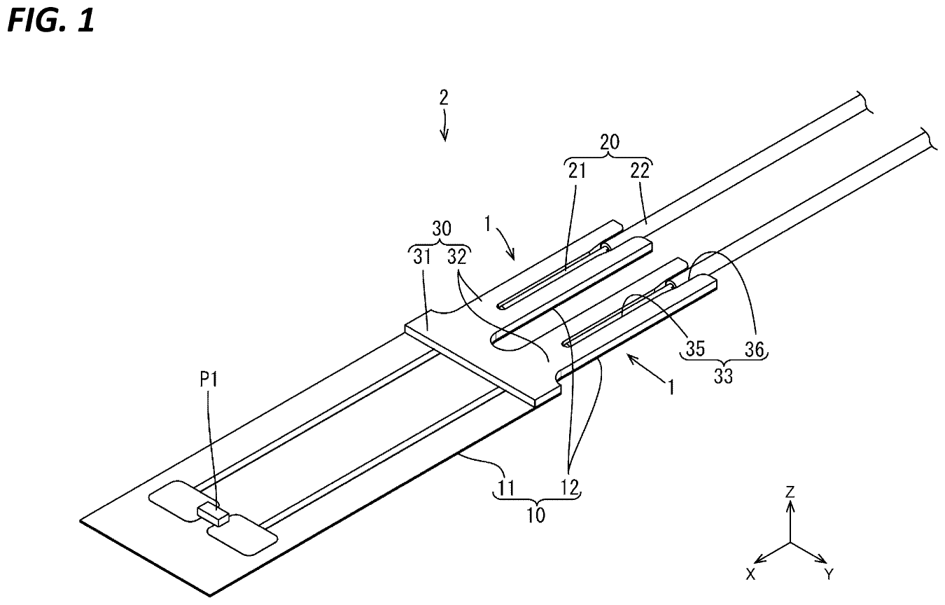

A first embodiment of the present disclosure is described with reference to FIGS. 1 to 9. In the following description, a direction indicated by an arrow Z is referred to as an upward direction, a direction indicated by an arrow X is referred to as a forward direction and a direction indicated by an arrow Y is referred to as a leftward direction. Note that, for a plurality of identical members, only some members may be denoted by a reference sign and the other members may not be denoted by the reference sign.

As shown in FIG. 1, an application example of connection structures 1 of wires 20 and a circuit board 10 (hereinafter, referred to as the connection structures 1) to a temperature measurement unit 2 is described in this embodiment. The temperature measurement unit 2 is provided with the circuit board 10 mounted with a thermistor P1, the wires 20 and a rigid board 30.

### Circuit Board

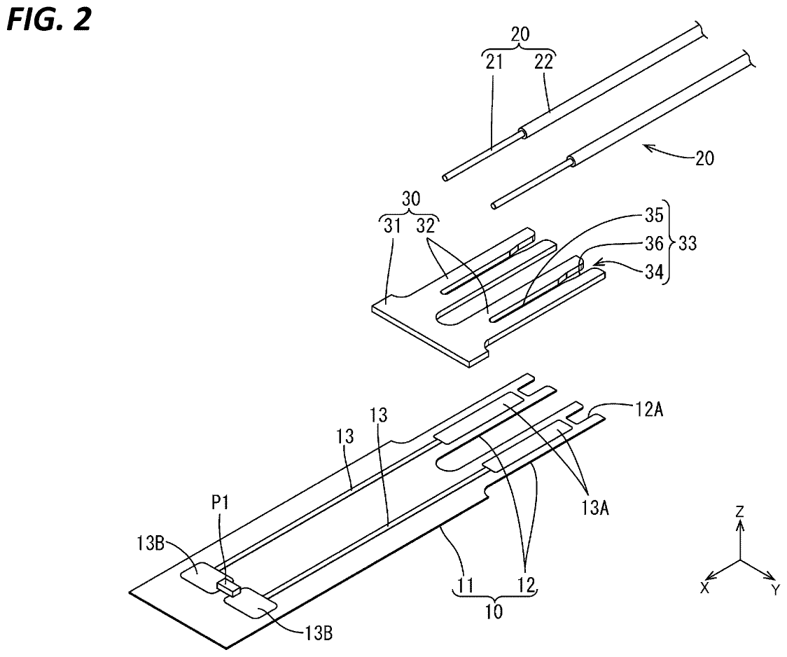

The circuit board 10 of this embodiment is a flexible board. As shown in FIG. 2, the circuit board 10 has a shape elongated in a front-rear direction as a whole. The circuit board 10 is provided with a body portion 11 substantially rectangular in a plan view and two first extending portions 12 extending rearward from the rear end of the body portion 11. The two first extending portions 12 are arranged side by side in a lateral direction. The circuit board 10 is configured by forming conductive paths 13 on a surface of a flexible insulating sheet by a printed wiring technique.

### Wire Lands

The circuit board 10 is provided with two conductive paths 13 extending in the front-rear direction. The two conductive paths 13 are arranged side by side in the lateral direction. A wire land 13A is formed on one end part (rear end part) of the conductive path 13. An element land 13B is formed on the other end part (front end part) of the conductive path 13. Two wire lands 13A are respectively disposed at positions near rear end parts of the first extending portions 12. The wires 20 are respectively connected to the two wire lands 13A by soldering. A recess 12A recessed forward from the rear end of the first extending portion 12 is provided at a position of the first extending portion 12 behind the wire land 12A.

The thermistor P1 is arranged in a lateral central part at a position near a front end part of the body portion 11. The thermistor P1 is connected to two element lands 13B provided on two conductive paths 13. The two element lands 13B are respectively connected to electrodes of the thermistor P1 by soldering.

### Wires

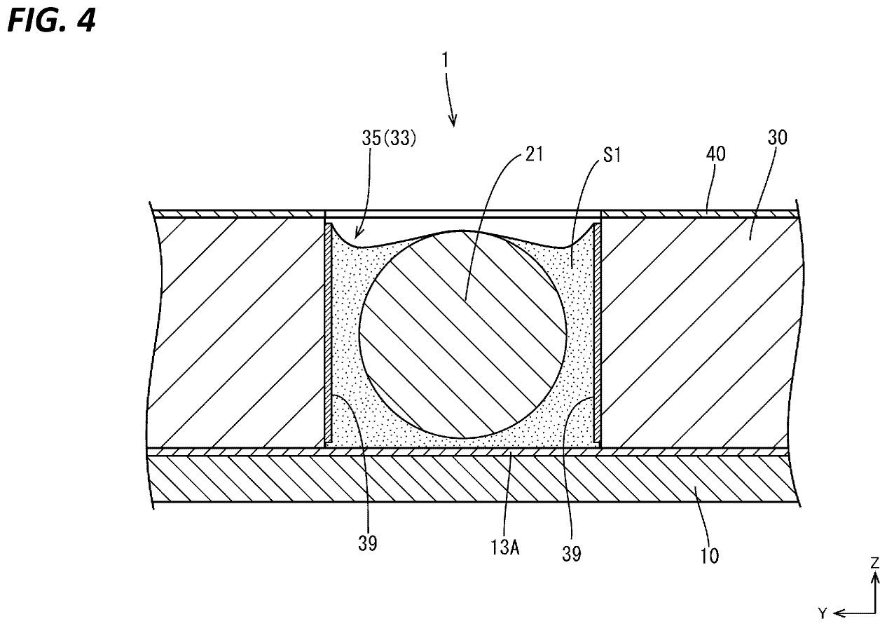

The temperature measurement unit 2 of this embodiment is connected to two wires 20. The wires 20 are connected to a device (not shown) for measuring a resistance value of the thermistor P1 via an unillustrated connector. The wire 22 includes a core wire 21 and an insulation coating 22 covering the outer periphery of the core wire 21. In an end part of the wire 20, the insulation coating 22 is removed to expose the core wire 21. As shown in FIG. 4, the core wire 21 is connected to the wire land 13A of the circuit board 10 by soldering.

### Rigid Board

The rigid board 30 is formed, for example, by impregnating a fiberglass cloth with an epoxy resin to harden the fiberglass cloth. As shown in FIG. 2, the rigid board 30 is substantially gate-shaped in a plan view. The rigid board 30 includes a base portion 31 substantially rectangular in the plan view and two second extending portions 32 extending rearward from the rear end of the base portion 31. The two second extending portions 32 are arranged side by side in the lateral direction. As shown in FIG. 1, the rigid board 30 is disposed to overlap the circuit board 10 in a thickness direction of the circuit board 10 (vertical direction). For example, the rigid board 30 is so overlapped on the circuit board 10 that a thickness direction of the rigid board 30 is along the thickness direction of the circuit board 10. The lower surface of the rigid board 30 is bonded to the upper surface of the circuit board 10 by an adhesive or the like. The respective second extending portions 32 are disposed at positions overlapping the respective first extending portions 12 in the vertical direction. The base portion 31 is disposed at a position overlapping a rear end part of the body portion 11 in the vertical direction.

### Accommodating Portion, Opening End

As shown in FIG. 2, each second extending portion 32 includes an accommodating portion 33 penetrating in the vertical direction and open rearward (an example of a direction orthogonal to the thickness direction). The accommodating portion 33 extends in the front-rear direction. The accommodating portion 33 includes, for example, an opening end 34 open rearward, a core wire accommodating portion 35 for accommodating the core wire 21 and an insulation coating accommodating portion 36 for accommodating the insulation coating 22.

### Core Wire Accommodating Portion, Insulation Coating Accommodating Portion

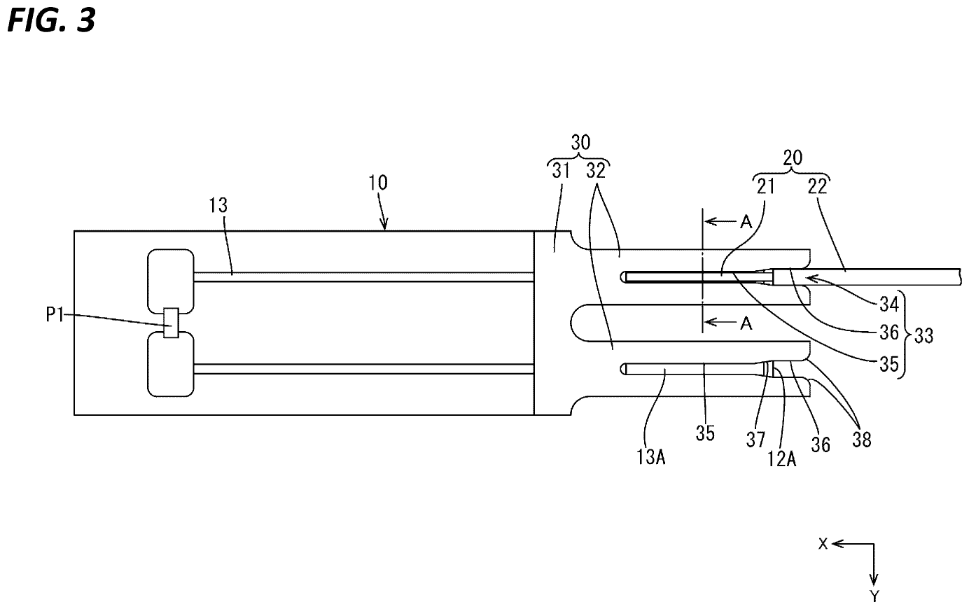

As shown in FIG. 3, the core wire accommodating portion 35 is disposed on a side (front side) opposite to the opening end 34 in the accommodating portion 33. For example, the core wire accommodating portion 35 has a length, which is about ¾ of the accommodating portion 33 in the front-rear direction. The insulation coating accommodating portion 36 is disposed continuously with the core wire accommodating portion 35 on the side of the opening end 34 (rear side). For example, the insulation coating accommodating portion 36 has a length, which is about ¼ of the accommodating portion 33 in the front-rear direction.

A width (dimension in the lateral direction) of the core wire accommodating portion 35 is set to be somewhat larger than a thickness of the core wire 21. A width of the insulation coating accommodating portion 36 is set to be somewhat larger than a thickness of the insulation coating 22 (wire 20). Further, the width of the insulation coating accommodating portion 36 is larger than that of the core wire accommodating portion 35. The rear end of the core wire accommodating portion 35 and the front end of the insulation coating accommodating portion 36 are smoothly connected by an inclined portion 37 inclined to widen a width of the accommodating portion 33 toward the rear side.

### Round Portions

The insulation coating accommodating portion 36 includes rounded round portions 38 in an end region including the opening end 34. The round portions 38 smoothly connect left and right inner walls of the insulation coating accommodating portion 36 and the rear end of the second extending portion 32. By providing the round portions 38, the insulation coating accommodating portion 36 is formed to be wider toward the opening end 34.

The accommodating portion 33 is disposed to overlap the wire land 13A in the vertical direction. In a plan view, at least a part of the wire land 13A is disposed inside the accommodating portion 33. In this embodiment, the wire land 13A is disposed to overlap the entire core wire accommodating portion 35 and a front part of the inclined portion 37. As shown in FIG. 4, a width of the wire land 13A is set to be larger than that of the core wire accommodating portion 35 in this embodiment. Both end parts in a width direction of the wire land 13A are disposed to face the lower surface of the rigid board 30 disposed on both sides of the core wire accommodating portion 35.

The core wire 21 accommodated in the core wire accommodating portion 35 is placed on the wire land 13A. Solder S1 for connecting the core wire 21 and the wire land 13A is filled into the core wire accommodating portion 35. In the thickness direction of the circuit board 10, it can be suppressed that the solder S1 protrudes beyond the rigid board 30. Thus, the shape and height of the solder S1 are easily controlled by providing the accommodating portion 33. Thus, the connection structure 1 is easily reduced in height.

### Plated Portions

In this embodiment, the accommodating portion 33 includes plated portions 39 formed on at least parts of the inner walls of the accommodating portion 33. The plated portions 39 are, for example, made of copper, tin, nickel or the like. Since the wettability of the solder S1 to the inner walls of the accommodating portion 33 is improved by providing the plated portions 39, the solder S1 is more easily filled in the accommodating portion 33. Further, since the plated portions 39 are connected to the solder S1 together with the wire land 13A and the core wire 21, the connection strength of the solder S1 for connecting the core wire 21 and the wire land 13A can be enhanced. Therefore, a region where the plated portions 39 are provided preferably includes at least parts of the inner walls of the core wire accommodating portion 35. In this embodiment, the plated portions 39 are provided on the substantially entire inner walls of the accommodating portion 33.

In this embodiment, a dimension in the vertical direction of the plated portion 39 has a minus tolerance with respect to that of the rigid board 30. In this way, if manufacturing tolerances of the plated portion 39 become large, it can be suppressed that the plated portion 39 is formed on the upper surface of the rigid board 30. Accordingly, the adhesion of the solder S1 to the upper surface of the rigid board 30 can be suppressed. Further, it can be suppressed that the solder S1 is raised from the upper surface of the rigid board 30. Note that the dimension in the vertical direction of the plated portion 39 having a minus tolerance with respect to that of the rigid board 30 means that the dimension in the vertical direction of the plated portion 39 is a value equal to or less than that of the rigid board 30. Further, the upper end of the plated portion 39 may be located below the upper surface of the rigid board 30.

### Resist

The rigid board 30 includes a resist 40 on a surface (upper surface) to be disposed on a side opposite to the circuit board 10 in the thickness direction. The resist 40 is made of an insulating material and repels the solder S1 in a melted state. Thus, the adhesion of the solder S1 to the upper surface of the rigid board 30 can be suppressed.

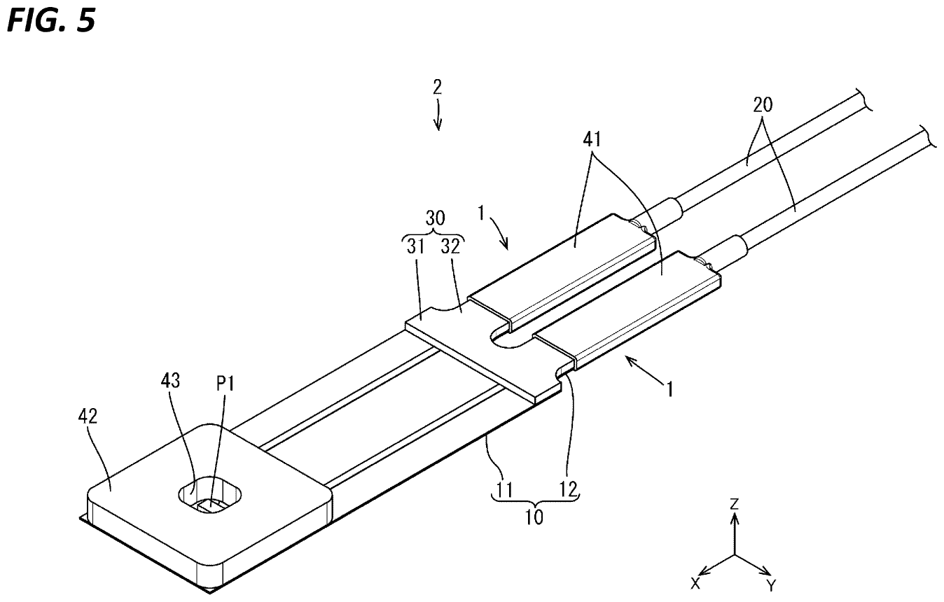

As shown in FIG. 5, the temperature measurement unit 2 may be provided with heat shrinkable tubes 41 for protecting the connection structures 1 and a protecting member 42 for protecting the thermistor P1. The heat shrinkable tube 41 covers the first extending portion 12, the second extending portion 32 and the end part of the wire 20 from outside. The protecting member 42 is in the form of a plate having a substantially rectangular shape in a plan view. An accommodation hole 43 penetrating through the protecting member 42 in the vertical direction is provided in a central part of the protecting member 42. The protecting member 42 is bonded to the upper surface of a front end part of the body portion 11 by an adhesive or the like. The thermistor Pl is disposed inside the accommodation hole 43. The protecting member 42 is, for example, made of a resilient material such as a spongy.

### Concerning Manufacturing Process of Temperature Measurement Unit

The temperature measurement unit 2 of this embodiment is configured as described above. An example of a manufacturing process of the temperature measurement unit 2 is described below.

The circuit board 10 is formed by the printed wiring technique and the thermistor P1 is mounted on the circuit board 10. The rigid board 30 is formed with the plated portions 39 and the resist 40.

Subsequently, the upper surface of the circuit board 10 and the lower surface of the rigid board 30 are bonded by the adhesive or the like. The first and second extending portions 12, 32 are arranged to overlap in the vertical direction.

The core wires 21 of a predetermined length are exposed in the end parts of the wires 20. The wires 20 having the core wires 21 exposed therefrom are inserted into the accommodating portions 33 of the rigid board 30. The core wires 21 are disposed in the core wire accommodating portions 35, and the insulation coatings 22 are disposed in the insulation coating accommodating portions 36. Further, lower parts of tip parts of the insulation coatings 22 are accommodated into the recesses 12A provided in the circuit board 10.

The solder S1 is filled into the accommodating portion 33. In particular, the solder S1 is filled into a groove-like space formed by the left and right inner walls of the core wire accommodating portion 35 and the upper surface of the wire land 13A. Since the plated portions 39 are provided on the inner walls of the accommodating portion 33, the solder S1 easily spreads in the accommodating portion 33. Further, since the plated portions 39 are formed to have a minus tolerance with respect to the dimension in the vertical direction of the inner walls of the accommodating portion 33 and the resist 40 is provided on the upper surface of the rigid board 30, the solder S1 hardly moves from the inside of the accommodating portion 33 to the upper surface of the rigid board 30. Therefore, the solder S1 can be retained in the accommodating portion 33 and the shape and height of the solder S1 can be stabilized.

### Concerning Usage Mode of Temperature Measurement Unit

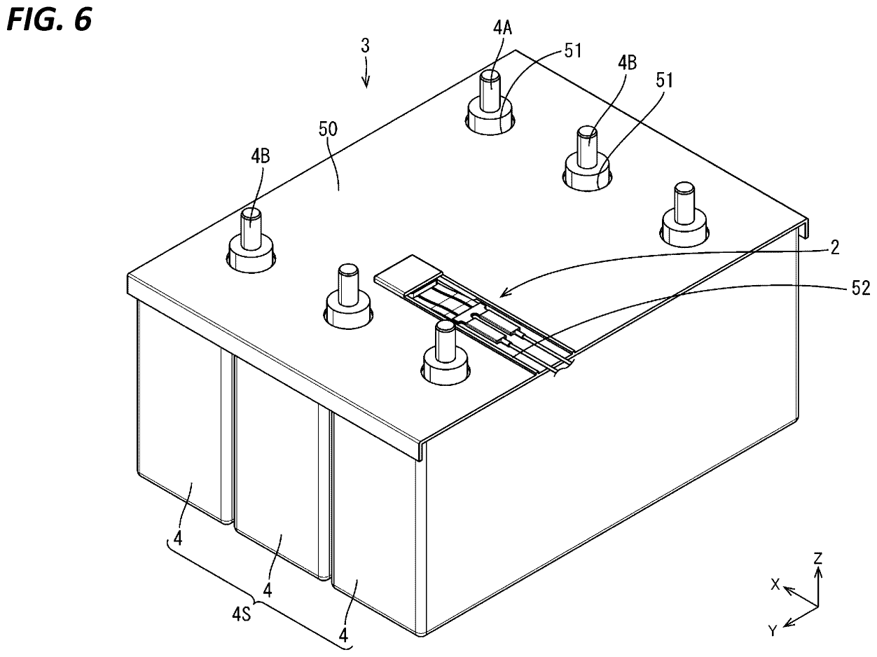

The temperature measurement unit 2 of this embodiment is attached to a temperature measurement object and used to measure a temperature of the temperature measurement object. The configuration of a battery module 3 for measuring a temperature of a power storage element 4 using the temperature measurement unit 2 is illustrated below with reference to FIGS. 6 to 9. This battery module 3 can be, for example, installed in a vehicle such as an electric vehicle or a hybrid vehicle.

As shown in FIG. 6, the battery module 3 is provided with the temperature measurement unit 2, a power storage element group 4S formed by stacking a plurality of the power storage elements 4 and a bracket 50 mounted on the upper surface of the power storage element group 4S. The power storage element 4 has a flat rectangular parallelepiped shape. An unillustrated power storage component is accommodated inside the power storage element 4. The power storage element 4 includes positive and negative electrode terminals 4A, 4B on the upper surface thereof.

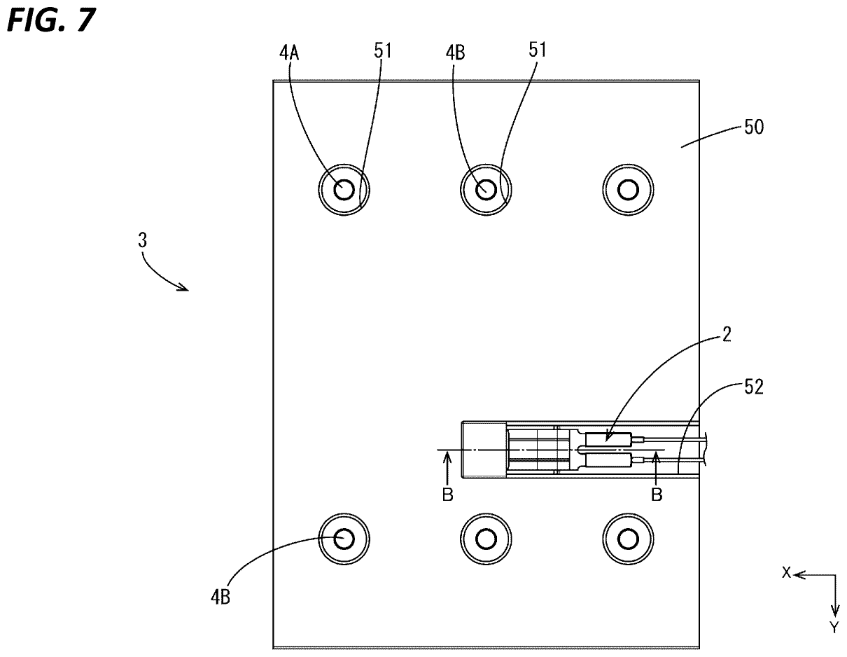

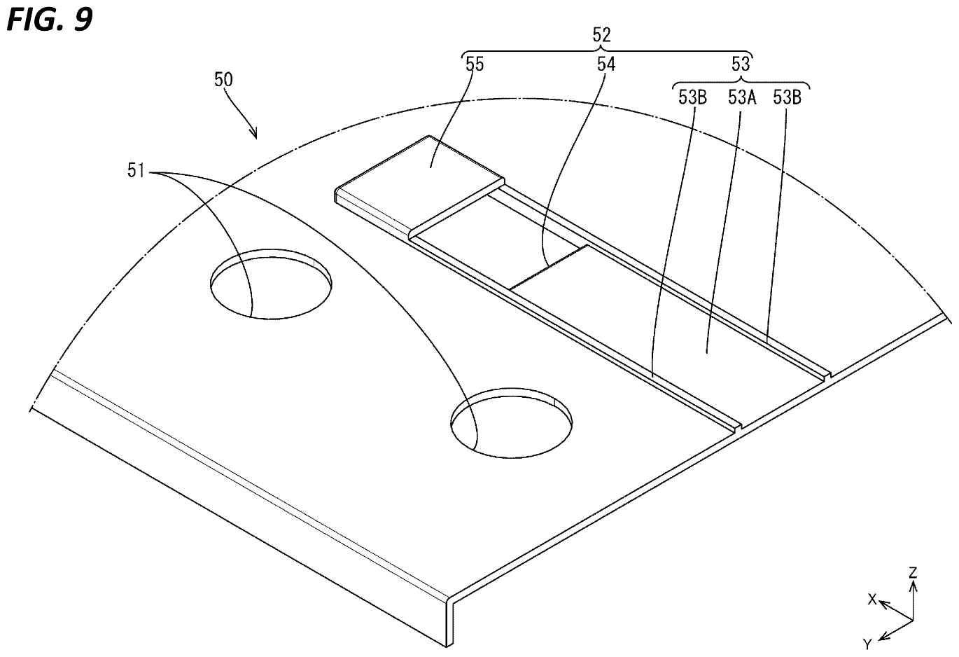

The bracket 50 is made of insulating synthetic resin. As shown in FIGS. 6 and 7, the bracket 50 is plate-like and includes electrode insertion holes 51 and a temperature measurement unit disposing portion 52. The electrode terminals 4A, 4B of the power storage elements 4 are inserted through the electrode insertion holes 51. The temperature measurement unit 2 is disposed in the temperature measurement unit disposing portion 52. As shown in FIG. 9, the temperature measurement unit disposing portion 52 includes a groove-like routing recess 53 extending in the front-rear direction, a temperature measurement opening 54 and a pressing wall 55. The routing recess 53 includes a bottom wall 53A and a pair of side walls 53B extending upward from both side edges of the bottom wall 53A. The pair of side walls 53B extend upward from the upper surface of the bracket 50. The temperature measurement opening 54 is disposed in a front end part of the temperature measurement unit disposing portion 52 and penetrates through the bottom wall 53A in the vertical direction. The pair of side walls 53B are wall portions forming the temperature measurement opening 54. Upper end parts of the pair of side walls 53B are connected by the pressing wall 55 in a front part of the temperature measurement opening 54. The pressing wall 55 covers the front part of the temperature measurement opening 54 from above.

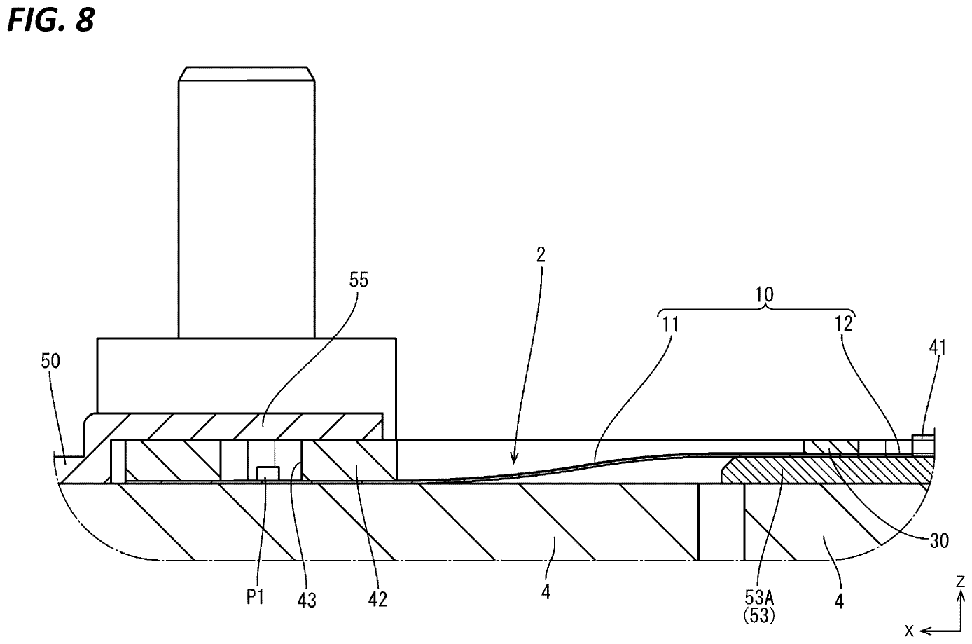

As shown in FIG. 8, a rear half of the temperature measurement unit 2, in particular a rear end part of the body portion 11, the first extending portions 12, the rigid board 30, the wires 20 and the heat shrinkable tubes 41, is disposed in the routing recess 53. A front end part of the temperature measurement unit 2, in particular a front end part of the body portion 11, the thermistor P1 and the protecting member 42, is disposed between the upper surface of the power storage element 4 and the pressing wall 55. The protecting member 42 made of the resilient material is pressed downward by the pressing wall 55. That is, an interval between the upper surface of the power storage element 4 and the lower surface of the pressing wall 55 is set to be somewhat smaller than a thickness of the protecting member 42 in a natural state. In this way, the front end part of the body portion 11 mounted with the thermistor P1 is pressed against the upper surface of the power storage element 4 as the temperature measurement object.

The front end part of the body portion 11 is placed on the upper surface of the power storage element 4, and the rear end part thereof is placed on the bottom wall 53A of the routing recess 53. Thus, the front end part of the body portion 11 is located below the rear end part thereof. However, since the circuit board 10 is flexible in this embodiment, a position deviation in the vertical direction between the front and rear end parts of the body portion 11 can be absorbed by the deflected shape of an intermediate part of the body portion 11.

Since the temperature measurement unit 2 is disposed in the vehicle, it is assumed that vibration, a stress for pulling the wires 20 or the like is applied. Since the plated portions 39 are provided on the inner walls of the accommodating portions 33 in this embodiment, the connection strength of the solder S1 is improved. Therefore, the electrical connection of the wires 20 and the circuit board 10 is easily ensured also for vibration in the vehicle.

Since the accommodating portion 33 includes the insulation coating accommodating portion 36 in this embodiment, a stress to the wire 20 is hardly concentrated on the core wire 21. Thus, the breakage of a part of the core wire 21 not covered by the solder S1 and the insulation coating 22 can be suppressed. Further, in this embodiment, the insulation coating accommodating portion 36 includes the round portions 38 and no sharp corner parts are formed in the end part of the accommodating portion 33 on the side of the opening end 34. Thus, in a vibration environment, it can be suppressed that the insulation coating 22 is damaged by contacting the end part of the accommodating portion 33 on the side of the opening end 34.

### Functions and Effects of First Embodiment

According to the first embodiment, the following functions and effects are achieved.

The connection structure 1 of the wire 20 and the circuit board 10 according to the first embodiment is provided with the wire 20 including the core wire 21 and the insulation coating 22 covering the outer periphery of the core wire 21, the circuit board 10 including the wire land 13A to be connected to the core wire 21 by soldering, and the rigid board 30 to be disposed to overlap the circuit board 10 in the thickness direction of the circuit board 10 (vertical direction). The rigid board 30 includes the accommodating portion 33 penetrating in the thickness direction and open in the direction orthogonal to the thickness direction. The accommodating portion 33 includes the core wire accommodating portion 35 for accommodating the core wire 21 and is disposed to overlap the wire land 13A in the thickness direction.

According to this configuration, the shape and the dimension in the thickness of the solder S1 are easily controlled by filling the solder S1 for connecting the wire 20 and the circuit board 10 into the accommodating portion 33. Thus, it can be suppressed that the connection structure 1 of the wire 20 and the circuit board 10 is enlarged in the thickness of the circuit board 10 by the solder S1. Therefore, the connection structure 1 of the wires 20 and the circuit board 10 can be reduced in height.

In the first embodiment, the accommodating portion 33 includes the plated portions 39 formed on at least parts of the inner walls of the accommodating portion 33.

According to this configuration, the solder S1 is more easily filled into the inside of the accommodating portion 33. Further, by connecting the solder S1 and the plated portions 39, the connection strength of the solder S can be enhanced.

In the first embodiment, the dimension in the thickness direction of the plated portion 39 has a minus tolerance with respect to the dimension in the thickness direction of the rigid board 30.

According to this configuration, it can be suppressed that the plated portions 39 are formed outside the accommodating portion 33. Thus, the leakage of the solder S1 to the outside of the accommodating portion 33 can be suppressed.

In the first embodiment, the accommodating portion 33 includes the opening end 34 open in the direction orthogonal to the thickness direction (rearward) and the insulation coating accommodating portion 36 disposed continuously with the core wire accommodating portion 35 on the side of the opening end 34 for accommodating the insulation coating 22.

According to this configuration, the insulation coating 22 can be accommodated into the accommodating portion 33. Thus, a part of the wire 20 accommodated in the insulation coating accommodating portion 36 can be restricted from moving with respect to the rigid board 30. Therefore, it can be suppressed that a stress is generated in a connected part of the core wire 21 and the wire land 13A by a stress or vibration applied to the wire 20. Further, it can be suppressed that the core wire 21 is damaged in the part not covered by the solder S1 due to the concentration of the stress or vibration applied to the wire 20 on the core wire 21.

In the first embodiment, the insulation coating accommodating portion 36 includes the rounded round portions 38 in the end region including the opening end 34 and is formed to be wider toward the opening end 34.

According to this configuration, it can be suppressed that the insulation coating 22 is damaged by contacting the end part of the accommodating portion 33 on the side of the opening end 34.

In the first embodiment, the rigid board 30 includes the resist 40 on the surface (upper surface) to be disposed on the side opposite to the circuit board 10 in the thickness direction.

According to this configuration, the adhesion of the solder S1 to the surface of the rigid board 30 can be suppressed.

The temperature measurement unit 2 according to the first embodiment is provided with the connection structures 1 of the wires 20 and the circuit board 10 and the thermistor P1 to be mounted on the circuit board 10.

According to this configuration, the temperature measurement unit 2 can be reduced in height.

### Second Embodiment

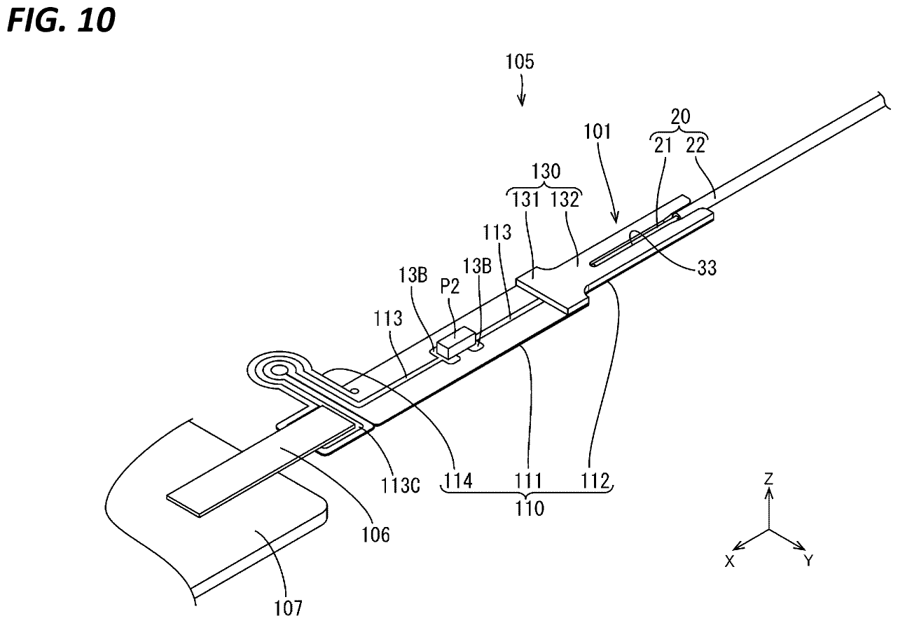

A second embodiment of the present disclosure is described with reference to FIG. 10. In this embodiment, an application example of a connection structure 101 of a wire 20 and a circuit board 110 (hereinafter, referred to as the connection structure 101) to a fuse unit 105 is described. Differently from the first embodiment, the fuse unit 105 is provided with one connection structure 101. That is, one wire 20 and one circuit board 110 are connected in the fuse unit 105. In the following description, members configured similarly to those of the first embodiment are denoted by the same reference signs as in the first embodiment and may not be described in detail.

The fuse unit 105 is provided with the circuit board 110 mounted with a chip fuse P2, a rigid board 130 and the wire 20. The circuit board 110 is a flexible board. The circuit board 110 is provided with a body portion 111 substantially rectangular in a plan view, one first extending portion 112 extending rearward from a rear end part of the body portion 111 and a stretching portion 114 provided on a front side of the body portion 111. The stretching portion 114 includes cuts and is formed into a crank shape. The stretching portion 114 is displaceable in a vertical direction, a lateral direction and a front-rear direction by a predetermined length with respect to the body portion 111.

The circuit board 110 is provided with two conductive paths 113. Out of the two conductive paths 113, the conductive path 113 disposed in a rear part of the circuit board 1110 includes a wire land (not shown) disposed in a rear end part thereof and an element land 13B disposed in a front end part thereof. Note that the wire land is concealed by the rigid board 130 and the wire 20 in FIG. 10, but the configuration thereof is similar to that of the wire lands 13A of the first embodiment. Out of the two conductive paths 113, the conductive path 113 disposed in a front part of the circuit board 10 includes an element land 13B disposed in a rear end part thereof and a busbar-side land 113C disposed in a front end part thereof.

The busbar-side land 113C is disposed in the stretching portion 114. The busbar-side land 113C is connected to a rear end part of a small metal piece 106 by welding or the like. A front end part of the small metal piece 106 is connected to a busbar 107 by welding or the like. That is, the busbar-side land 113C is electrically connected to the busbar 107 via the small metal piece 106. The busbar 107 is connected to an electrode terminal of an unillustrated power storage element. The power storage elements are stacked to configure a power storage element group, and disposed in a vehicle as in the first embodiment.

The chip fuse P2 is disposed in a central part of the body portion 111. The chip fuse P2 is connected to the two element lands 13B provided on the two conductive paths 113. The two element lands 13B are respectively connected to electrodes of the chip fuse P2 by soldering.

The rigid board 130 includes a base portion 131 and one second extending portion 132 extending rearward from the base portion 131. The rigid board 130 is configured similarly to the rigid board 30 of the first embodiment except that the number of the second extending portion 132 is different. The wire 20 is disposed in an accommodating portion 33 and connected to the wire land by solder (not shown) filled into the accommodating portion 33.

The fuse unit 105 of this embodiment is assumed as a part of a so-called voltage detection line. The wire 20 is connected to an ECU (Electronic Control Unit) or the like via an unillustrated connector. The ECU is mounted with a microcomputer, elements and the like, and has a known configuration provided with functions of detecting a voltage, a current, a temperature and the like of each power storage element and controlling the charge/discharge of each power storage element.

This embodiment is configured as described above. Functions and effects of this embodiment are similar to those of the first embodiment and, hence, not described.

### Other Embodiments

(1) Although the core wire accommodating portion 35 and a part of the inclined portion 37 of the accommodating portion 33 are disposed to overlap the wire land 13A in the first embodiment, there is no limitation to this and at least a part of an accommodating portion only has to be disposed to overlap a wire land.
(2) Although the circuit board 10, 110 is a flexible board in the first and second embodiments, there is no limitation to this and a circuit board may be a rigid board.
(3) Although the circuit board 10 is provided with the thermistor P1 in the first embodiment and the circuit board 110 is provided with the chip fuse P2 in the second embodiment, there is no limitation to this and a circuit board may be provided with an electronic component different from these. Further, a circuit board may not be provided with any electronic component.
(4) Although the two wires 20 are connected to one circuit board 10 in the first embodiment and one wire 20 is connected to one circuit board 110 in the second embodiment, there is no limitation to this and the number of wires to be connected to one circuit board can be arbitrarily selected.
(5) Although the temperature measurement unit 2 is illustrated in the first embodiment and the fuse unit 105 is illustrated in the second embodiment, there is no limitation to this and the connection structure of the wire and the circuit board of the present disclosure may be applied to a configuration different from these.
(6) The accommodating portion 33 may not include the insulation coating accommodating portion 36. For example, the accommodating portion 33 may include the opening end 34 and the core wire accommodating portion 35 for accommodating the core wire 21 without including the insulation coating accommodating portion 36.

### LIST OF REFERENCE NUMERALS

1, 101: connection structure of wire and circuit board
2: temperature measurement unit
3: battery module
4: power storage element
4A, 4B: electrode terminal
4S: power storage element group
10, 110: circuit board
11, 111: body portion
12, 112: first extending portion
12A: recess
13, 113: conductive path
13A: wire land
13B: element land
20: wire
21: core wire
22: insulation coating
30, 130: rigid board
31, 131: base portion
32, 132: second extending portion
33: accommodating portion
34: opening end
35: core wire accommodating portion
36: insulation coating accommodating portion
37: inclined portion
38: round portion
39: plated portion
40: resist
42: heat shrinkable tube
42: protecting member
43: accommodation hole
50: bracket
51: electrode insertion hole
52: temperature measurement unit disposing portion
53: routing recess
53A: bottom wall
53B: side wall
54: temperature measurement opening
55: pressing wall
105: fuse unit
106: small metal piece
107: busbar
113C: busbar-side land
114: stretching portion
P1: thermistor
P2 chip fuse
S1: solder

1. A connection structure of a wire and a circuit board, comprising:
a wire including a core wire and an insulation coating covering an outer periphery of the core wire;
a circuit board including a wire land to be connected to the core wire by soldering; and
a rigid board to be disposed to overlap the circuit board in a thickness direction of the circuit board,
the rigid board including an accommodating portion penetrating in the thickness direction and open in a direction orthogonal to the thickness direction, and
the accommodating portion including a core wire accommodating portion for accommodating the core wire, the accommodating portion being disposed to overlap the wire land in the thickness direction.

2. The connection structure of the wire and the circuit board of claim 1, wherein the accommodating portion includes a plated portion formed on at least a part of an inner wall of the accommodating portion.

3. The connection structure of the wire and the circuit board of claim 2, wherein a dimension in the thickness direction of the plated portion has a minus tolerance with respect to a dimension in the thickness direction of the rigid board.

4. The connection structure of the wire and the circuit board of claim 1, wherein the accommodating portion includes an opening end open in a direction orthogonal to the thickness direction and an insulation coating accommodating portion disposed continuously with the core wire accommodating portion on the opening end side for accommodating the insulation coating.

5. The connection structure of the wire and the circuit board of claim 4, wherein the insulation coating accommodating portion includes a rounded round portion in an end region including the opening end and is formed to be wider toward the opening end.

6. The connection structure of the wire and the circuit board of claim 1, wherein the rigid board includes a resist on a surface to be disposed on a side opposite to the circuit board in the thickness direction.

7. A temperature measurement unit, comprising:
the connection structure of the wire and the circuit board of claim 1; and
a thermistor to be mounted on the circuit board.
